(19) United States
(12) Patent Application Publication
(10) Pub. No.: US 2012/0260848 A1
(43) Pub. Date: Oct. 18, 2012

(54) Single crystal growth method for vertical high temperature and high pressure group III-V compound

(75) Inventors: Zhi He, New Taipei City (TW); Xiao-Yu Hu, New Taipei City (TW)

(73) Assignees: Xiao-Yu Hu, New Taipei City (TW); Zhi He, New Taipei City (TW); DingTen Industrial Inc. (Taiwan company), Taipei City (TW)

(21) Appl. No.: 13/443,965

(22) Filed: Apr. 11, 2012

(30) Foreign Application Priority Data
Apr. 12, 2011 (TW) 100112534

(51) Int. Cl. C30B 11/12

(52) U.S. Cl. 117/77

(57) ABSTRACT

The invention discloses a single crystal growth method for a vertical high temperature and high pressure group III-V compound. A vertical high temperature and high pressure stove is capable of providing a group III element fusion zone with a temperature equal to or greater than that of a composition melting point and providing a group V element provision zone below the group III element fusion zone. The stove provides steam to the group III element fusion zone and the group V element provision zone at a temperature greater than evaporation temperature. The compound synthesis of a group III element and a group V element is completed in the group III element fusion zone, and an in-situ growth of single crystal is completed in the group III element fusion zone, thereby preventing the growth of the rich group III element and increasing the single crystal process efficiency.

### BACKGROUND OF THE INVENTION

1. Field of the Invention

The present invention relates to a synthesis and single crystal growth technique for group III-V compound.

2. Description of the Related Art

In rapid development of group III-V compound semiconductors in photoelectric industries, the demand of group III-V compound is to be steadily increased. Taking indium phosphide of group III-V compound for example, due to indium phosphide having dissociation pressure of 2.75 Mpa at its fusing point temperature, it is difficult to perform direct synthesis and crystal growth process in the single crystal stove. In view of this, it is generally high purity phosphorus and high purity indium are preliminarily synthesize in a high pressure stove, and then the synthesized compounds are placed in the single crystal stove for crystal growth.

How to complete high-purity polycrystalline synthesis and high-quality single crystalline growth are the basic and important factors for an electronic product with low price and high quality. The single growth is a conversion process of liquid phase and solid phase. In this conversion process, molten indium phosphide compound shall be processed according to special direction and speed settings to release latent heat of crystallization and to reduce free energy, so that perfect molecule allocation and complete crystal growth can be obtained.

‘Horizontal Bridgman method’ disclosed in 1950 is the earliest single crystal method for indium phosphide. In 1968, ‘Liquid Encaps method’ disclosed by J. B. Mullink is utilized to produce large-sized single crystals. In 1986, ‘Vertical Gradient Freezing (VGF) method’ disclosed by Monberg et al in Bell Lab., U.S., is successfully utilized to perform single crystal growth for group III-V materials.

However, it is time-consuming and easily to be contaminated when a temperature-lowered, synthesized indium phosphide polycrystalline removed out of a synthesis stove is placed in a single crystal stove for temperature-rising single crystal growth, and therefore many researches are focused on developing the skill of in-situ synthesis and single crystal growth. It can be seen in the world that only the LEC method which has been developed and improved is able to perform the synthesis of indium phosphide in the LEC stove, thereby completing the in-situ synthesis and single crystal growth.

Moreover, in practical applications, the current in-situ synthesis and single crystal growth methods, generally having disadvantages and inconveniences, such as high-cost facilities, low growth speed, high technical skills required, high contaminations and rich indium formed indium phosphide, are incapable of increasing the efficiency of the single crystal growth and unsuitable for mass production.

### BRIEF SUMMARY OF THE INVENTION

In view of this, the main purpose of the present invention is to provide a low cost single crystal growth method for a vertical high temperature and high pressure group III-V compound.

For realizing the purposes, functions and effects above, the present invention adopts the following technical projects. Te single crystal growth method is mainly completed by a vertical high temperature and high pressure stove. The vertical high temperature and high pressure stove is capable of providing a group III element fusion zone with a temperature equal to or greater than that of a composition melting point and providing a group V element provision zone below the group III element fusion zone under high pressure protection, and the vertical high temperature and high pressure stove providing steam to the group III element fusion zone and the group V element provision zone at a temperature greater than the evaporation temperature, and the group III element fusion zone in which a compound synthesis of a group III element and a group V element as chemical element periodic table is rapidly completed. The single crystal growth method includes the synthesizing steps of:

a) a step of filling the group V element, in which a high-purity group V element is placed on a bottom of a quartz tube;

b) a step of filling a crystal seed and the group III element, in which the crystal seed is disposed on a bottom of a pyrolytic boron nitride crucible and a high-purity group III element is placed in the pyrolytic boron nitride crucible;

c) a step of filling the group III element in the quartz tube, in which the pyrolytic boron nitride crucible filled with the crystal seed and the high-purity group III element is disposed in the quartz tube filled with the group V element at a predetermined height inside the quartz tube;

d) a step of evacuating the quartz tube, in which the quartz tube is evacuated and an opening of the quartz tube is sealed;

e) a step of filling the quartz tube in a pressure vessel, in which the sealed quartz tube filled with the group III element and the group V element is placed in the vertical high temperature and high pressure stove and the vertical high temperature and high pressure stove is closed;

f) a step of pressurizing and heating to a fusion synthesis temperature, in which the vertical high temperature and high pressure stove is pressurized by a high pressure nitrogen gas, a temperature rising of a heating module is performed that the heating module is heated to a gasification temperature of the group V element in correspondence to a heating unit of the group V element provision zone and is heated to the fusion synthesis temperature of the group III-V compound in correspondence to the fusion synthesis temperature of the group III element fusion zone or crystal growing zone in a heating unit;

g) a step of completing synthesis, in which the synthesis of the group III element and the group V element is completed when the heating module is kept at the fusion synthesis temperature for a specific period;

h) a step of completing crystal growing, in which the temperature of crystal seed is adjusted and bottom-up lowered so that crystal growing is started and finally the crystal growing is completed;

i) a step of releasing pressure and temperature, in which the temperature of the heating module is lowered to normal temperature so that the high pressure of the pressure vessel is lowered to a normal pressure; and

j) a step of removing single crystalline after the compound synthesis is completed, in which after the synthesis and the crystal growing of the group III element and the group V element are completed, the pressure vessel is opened for removing the quartz tube, and the quartz tube is destroyed for taking out the single crystalline.

With the concrete realization of technical projects above, the vertical high temperature and high pressure synthesis and the single crystal growth method of the present invention is capable of providing the raised synthesis growth temperature greater than the melting temperature of the compound and operating in the high pressure environment, using direct fusion as synthesis mechanism to replace diffusion methods and increasing the synthesis rate, effectively avoiding silicon contamination, obtaining a preferred synthesis mixture proportion of the compound in the synthesis growth process, and attaining less material waste in chip cutting process.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic flow chart showing a single crystal growth method for a vertical high temperature and high pressure group III-V compound;

FIG. 2 is a schematic view showing a simplified framework of a vertical high temperature and high pressure stove; and

FIG. 3 is a schematic diagram showing temperature distribution of compound synthesis performed in a vertical high temperature and high pressure stove.

### DETAILED DESCRIPTION OF THE INVENTION

The present invention provides a single crystal growth method for a vertical high temperature and high pressure group III-V compound, capable of completing a crystal growth of direct compound synthesis of a group III element and a group V element as chemical element periodic table in a high temperature and high pressure environment, such as group III-V compound comprising gallium arsenide, gallium phosphide or indium phosphide. In this embodiment, the group III-V compound is indium phosphide.

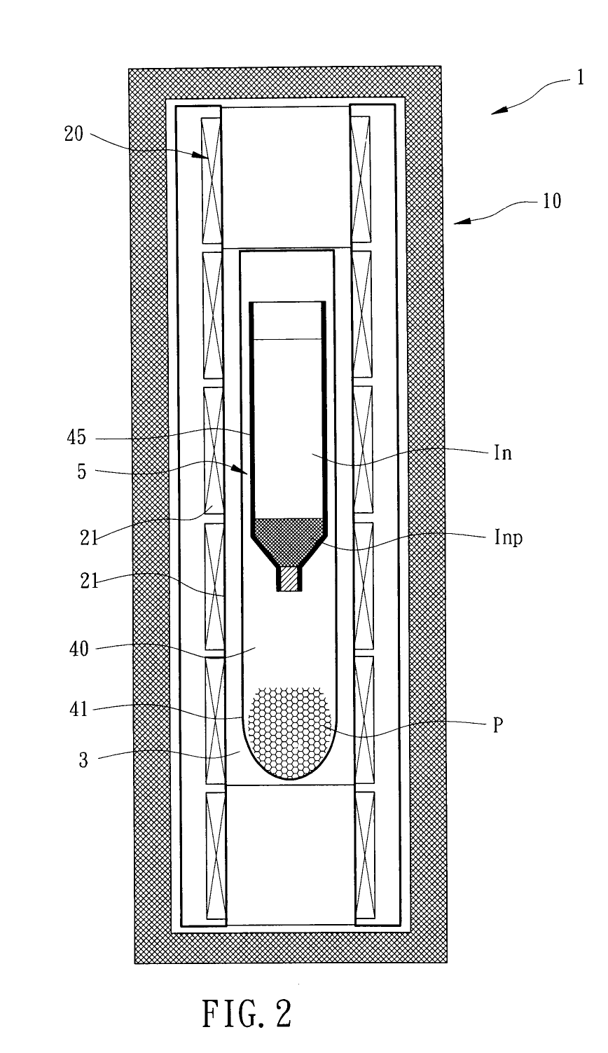

The single crystal growth method of the present invention is mainly completed by a vertical high temperature and high pressure stove 1. Under high pressure protection, the vertical high temperature and high pressure stove 1 is capable of providing a group III element fusion zone 3 with a temperature equal to or greater than that of a composition melting point, providing a group V element provision zone 5 below the group III element fusion zone 3, and providing steam to the group III element fusion zone 3 and the group V element provision zone 5 at a temperature greater than the evaporation temperature, and the synthesis and the in-situ growth of single crystal are rapidly completed in the group III element fusion zone 3. In this embodiment, the group III element fusion zone 3 is defined as a crystal growing zone or synthesis zone. In a preferred embodiment and a simplified structure shown in FIG. 2, the vertical high temperature and high pressure stove 1 of the present invention at least comprises a pressure vessel 10 vertically disposed on a land surface and a heating module 20 disposed in the pressure vessel 10.

The pressure vessel 10, capable of bearing 300 atmospheric pressure when being covered, can be filled with high pressure gas therein, and an industrial nitrogen gas is served as a pressure medium to provide a high pressure working environment and protect the vertical high temperature and high pressure stove 1.

The heating module 20 includes a heating space 25 utilized to fill the quartz tube therein and four or more sets of independent heating units 21 which are simultaneously corresponded to the heating space 25. In this embodiment, the maximum working temperature of the heating module 20 is designed at 1400 C. Taking four sets of independent heating units 21 as an example, the four sets of independent heating units 21 of the heating module 20 are bottom-up sequentially defined as a lower-end protective zone heating unit, a provision zone heating unit corresponding to the group III element fusion zone 3 of the vertical high temperature and high pressure stove 1, a crystal growing zone heating unit corresponding to the group V element provision zone 5 of the vertical high temperature and high pressure stove 1, and an upper-end protective zone heating unit. The upper-end protective zone heating unit and the lower-end protective zone heating unit are utilized to stabilize the internal temperature of the heating module 20 for temperature protection. Further, the provision zone heating unit is utilized to provide the group V element (e.g., red phosphorus) with an accurate gasification temperature in favor of controlling the pressure. The crystal growing zone heating unit is utilized to provide the group III element and the group V element (e.g., synthesis of phosphorus and indium) with sufficient and stable temperature for direct synthesis and crystal growth.

Accordingly, the formed vertical high temperature and high pressure stove structure has advantages of low cost, rapid production and in-situ synthesis and crystal growth.

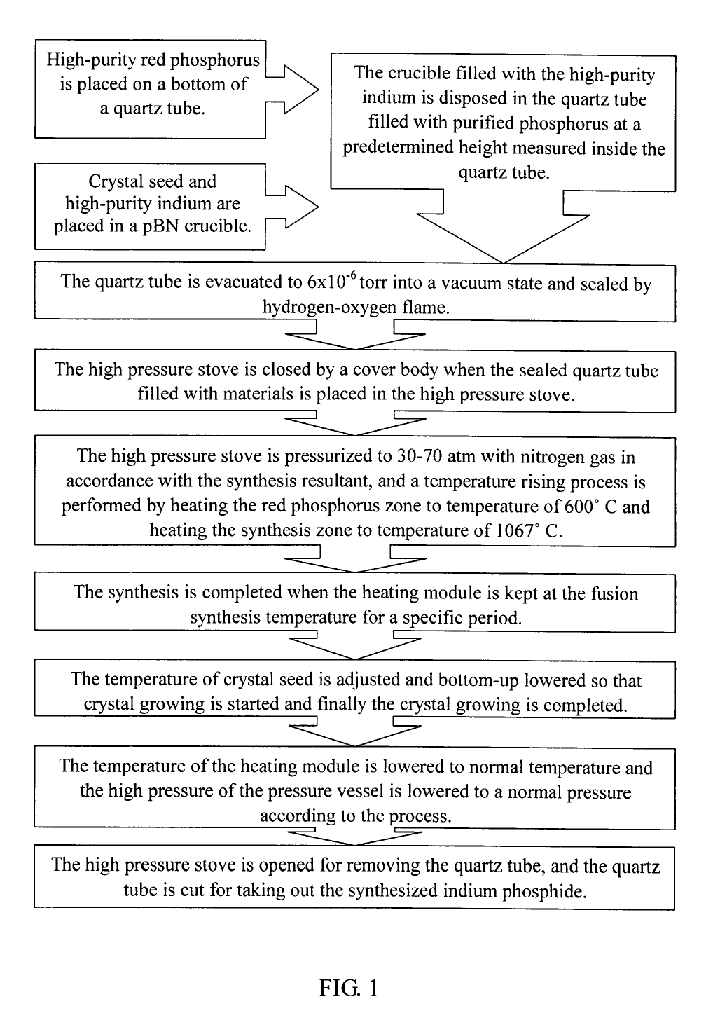

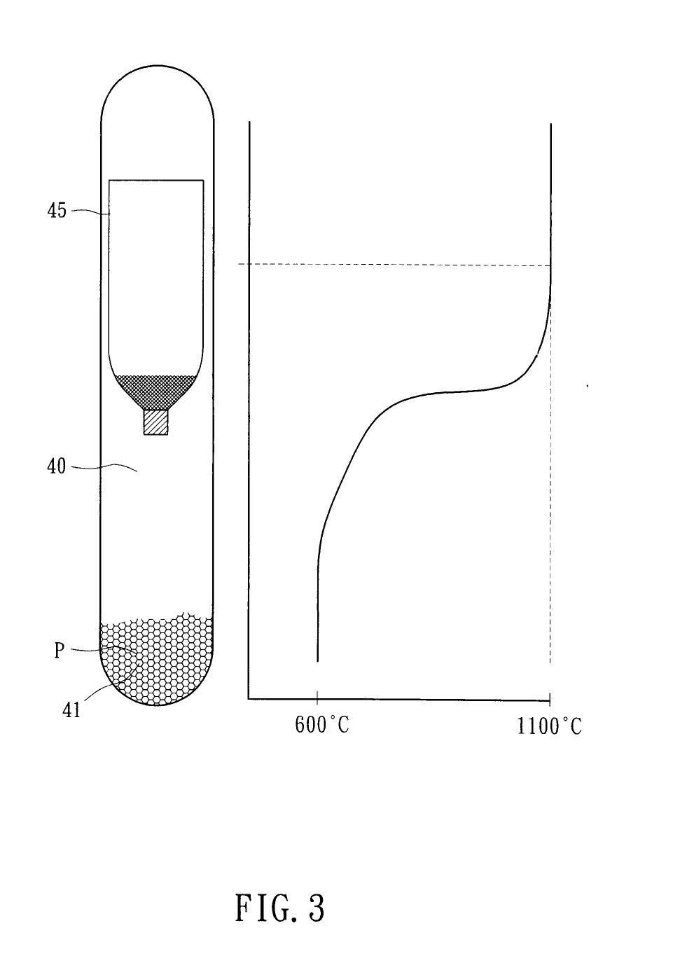

As shown in FIGS. 1, 2 and 3, the single crystal growth method for the vertical high temperature and high pressure group III-V compound of the present invention, which is incorporated with the vertical high temperature and high pressure stove 1 for synthesis, comprises the steps of:

a) a step of filling the group V element, in which a high-purity group V element is first installed on a bottom 41 of a quartz tube 40;

b) a step of filling a crystal seed and the group III element, in which the crystal seed is disposed on a bottom of a pyrolytic boron nitride (pBN) crucible 45 and a high-purity group III element is placed in the pBN crucible 45;

c) a step of filling the group III element in the quartz tube 40, in which the pBN crucible 45 filled with the crystal seed and the high-purity group III element is disposed in the quartz tube 40 filled with the group V element at a predetermined height inside the quartz tube 40;

d) a step of evacuating the quartz tube 40, in which when the quartz tube 40 is evacuated to 6×10⁻⁶ torr, an opening of the quartz tube 40 is sealed by hydrogen-oxygen flame;

e) a step of filling the quartz tube 40 in a pressure vessel 10, in which when the sealed quartz tube 40 filled with the group III element and the group V element is placed in the heating space 25 of the heating module 20 which is disposed in the pressure vessel 10 of the vertical high temperature and high pressure stove 1, the pressure vessel 10 of the vertical high temperature and high pressure stove 1 is closed;

f) a step of pressurizing and heating to a fusion synthesis temperature, in which, with a high pressure nitrogen gas, the pressure vessel 10 of the vertical high temperature and high pressure stove 1 is pressurized to 30-70 atm in accordance with the resultant, a temperature rising of a heating module 20 is performed that the heating module 20 is heated to a gasification temperature of the group V element (e.g., 600 C for red phosphorus) in correspondence to a heating unit of the group V element provision zone 5 and is heated to the fusion synthesis temperature of the group III-V compound (e.g., indium phosphide for 1062 C) in the heating unit 21 in correspondence to the fusion synthesis temperature the group III element fusion zone 3 or crystal growing zone;

g) a step of completing synthesis, in which the synthesis of the group III element and the group V element is completed when the heating module 20 is kept at the fusion synthesis temperature for a specific period;

h) a step of completing crystal growing, in which the temperature of crystal seed is adjusted and bottom-up lowered so that crystal growing is started and finally the crystal growing is completed;

i) a step of releasing pressure and temperature, in which the temperature of the heating module 20 is finally lowered to normal temperature and the high pressure of the pressure vessel 10 is finally lowered to a normal pressure; and

j) a step of removing single crystalline after the compound synthesis is completed, in which after the synthesis and the crystal growing of the group III element and the group V element are completed, the pressure vessel 10 is opened for removing the quartz tube 40, and the quartz tube 40 is destroyed for taking out the single crystalline (e.g., indium phosphide single crystalline).

According to the above description, it is understood that, when using the present invention to synthesize indium phosphide, the high purity red phosphorus (can be replaced by other group V elements in the chemical element periodic table, but it is represented by ‘phosphorus’ hereinafter) which is placed on the inner bottom 41 of the quartz tube 40 with one closed end is served as the group V element provision zone 5, and the high purity indium (can be replaced by other group III elements in the chemical element periodic table, but it is represented by ‘indium’ hereinafter) which is placed on the pBN crucible 45 or a quartz crucible disposed in the quartz tube 40 is served as the group III element fusion zone 3 (also referred to ‘synthesis zone’ or ‘crystal growing zone’). Incorporated with crystal growing techniques, a crystal seed zone which is located at the bottom 41 of the pBN crucible 45 or quartz crucible is needed to place different bend nematic crystal seeds. The bottom 41 of the pBN crucible 45 can be formed of funnel or straight tube shapes, in which the funnel shape has a slanted surface to be provided with various conclusions in accordance with different researches and reports. After the sealed, vacuum-evacuated quartz tube 40 is disposed in the vertical high temperature and high pressure stove 1 and the vertical high temperature and high pressure stove 1 is closed by a stove cover, the vertical high temperature and high pressure stove 1 is boosted by the nitrogen gas to a range of 30 to 70 atm, the temperature of the high-purity indium of the group III element fusion zone 3 is gradually increased to 1100 C according to the process, and the temperature of red phosphorus of the group V element provision zone 5 is gradually increased to 600 C according to the process. Then, the high purity indium phosphide can be obtained by using the phosphorus steam function to have contact reaction with the high temperature fusion indium, and indium can be completely synthesized into indium phosphide when the heating module 20 is kept at the fusion synthesis temperature for the specific period. Then, the crystal seed is partially fused by adjusting the temperature of the crystal seed zone, the temperature of crystal seed is bottom-up lowered so that crystal growing is started until the crystal growing is totally completed, and then temperature-releasing, annealing and cooling steps are performed according to the process, thus to complete the growth of indium phosphide polycrystalline.

The vertical high temperature and high pressure synthesis and the single crystal growth method of the present invention are capable of providing the raised synthesis growth temperature greater than the melting temperature of the compound and operating in the high pressure environment, using direct fusion as synthesis mechanism to replace diffusion methods and increasing the synthesis rate, and obtaining preferred synthesis mixture proportion of the compound in the synthesis growth process. Further, incorporated with the current VGF method or the current HB single crystal method, the in-situ single crystal growth method can effectively provide advantages of short production time, low cost and fewest contamination, preferred quality of single crystal with perfect outer diameter, and less material waste in chip cutting process.

What is claimed is:

1. A single crystal growth method for a vertical high temperature and high pressure group III-V compound, the single crystal growth method being mainly completed by a vertical high temperature and high pressure stove, the vertical high temperature and high pressure stove being capable of providing a group III element fusion zone with a temperature equal to or greater than that of a composition melting point and providing a group V element provision zone below the group III element fusion zone under high pressure protection, the vertical high temperature and high pressure stove providing steam to the group III element fusion zone and the group V element provision zone at a temperature greater than the evaporation temperature, and the group III element fusion zone in which a compound synthesis of a group III element and a group V element as chemical element periodic table is rapidly completed, the single crystal growth method comprising the synthesizing steps of:
a) a step of filling the group V element, in which a high-purity group V element is placed on a bottom of a quartz tube;
b) a step of filling a crystal seed and the group III element, in which the crystal seed is disposed on a bottom of a pyrolytic boron nitride crucible and a high-purity group III element is placed in the pyrolytic boron nitride crucible;
c) a step of filling the group III element in the quartz tube, in which the pyrolytic boron nitride crucible filled with the crystal seed and the high-purity group III element is disposed in the quartz tube filled with the group V element at a predetermined height inside the quartz tube;
d) a step of evacuating the quartz tube, in which the quartz tube is evacuated and an opening of the quartz tube is sealed;
e) a step of filling the quartz tube in a pressure vessel, in which the sealed quartz tube filled with the group III element and the group V element is placed in the vertical high temperature and high pressure stove and the vertical high temperature and high pressure stove is closed;
f) a step of pressurizing and heating to a fusion synthesis temperature, in which the vertical high temperature and high pressure stove is pressurized by a high pressure nitrogen gas, a temperature rising of a heating module is performed that the heating module is heated to a gasification temperature of the group V element in correspondence to a heating unit of the group V element provision zone and is heated to the fusion synthesis temperature of the group III-V compound in correspondence to in correspondence to the fusion synthesis temperature of the group III element fusion zone or crystal growing zone a heating unit;
g) a step of completing synthesis, in which the synthesis of the group III element and the group V element is completed when the heating module is kept at the fusion synthesis temperature for a specific period;
h) a step of completing crystal growing, in which the temperature of crystal seed is adjusted and bottom-up lowered so that crystal growing is started and finally the crystal growing is completed;
i) a step of releasing pressure and temperature, in which the temperature of the heating module is lowered to normal temperature so that the high pressure of the pressure vessel is lowered to a normal pressure; and
j) a step of removing single crystalline after the compound synthesis is completed, in which after the synthesis and the crystal growing of the group III element and the group V element are completed, the pressure vessel is opened for removing the quartz tube, and the quartz tube is destroyed for taking out the single crystalline.

2. The single crystal growth method for the vertical high temperature and high pressure group III-V compound as claimed in claim 1, wherein the single crystal growth method is applied to the synthesis and the crystal growing of the group III-V compound comprising gallium arsenide, gallium phosphide or indium phosphide.

3. The single crystal growth method for the vertical high temperature and high pressure group III-V compound as claimed in claim 1, wherein the synthesis the group V element is selected from phosphorus and the group III element is selected from indium.

4. The single crystal growth method for the vertical high temperature and high pressure group III-V compound as claimed in claim 1, wherein the step of filling the crystal seed and the group III element the crucible is selected from the pyrolytic boron nitride crucible.

5. The single crystal growth method for the vertical high temperature and high pressure group III-V compound as claimed in claim 1, wherein the step of evacuating the quartz tube the quartz tube has 6×10⁻⁶ torr of degree of vacuum therein.

6. The single crystal growth method for the vertical high temperature and high pressure group III-V compound as claimed in claim 1, wherein the step of evacuating the quartz tube the opening of the quartz tube is sealed by hydrogen-oxygen flame.

7. The single crystal growth method for the vertical high temperature and high pressure group III-V compound as claimed in claim 1, wherein the step of pressurizing and heating to the fusion synthesis temperature the vertical high temperature and high pressure stove has a pressure of 30 to 70 atm therein.

8. The single crystal growth method for the vertical high temperature and high pressure group III-V compound as claimed in claim 1, wherein the vertical high temperature and high pressure stove at least comprises a pressure vessel vertically disposed on a land surface and a heating module disposed in the pressure vessel, the heating module includes a heating space filled with the quartz tube and at least four sets of independent heating units corresponding to the heating space, and the at least four sets of independent heating units of the heating module are bottom-up sequentially defined as a protective zone heating unit, a provision zone heating unit, a crystal growing zone heating unit and a protective zone heating unit.
